(19) United States
(12) Patent Application Publication
(10) Pub. No.: US 2026/0171985 A1
(43) Pub. Date: Jun. 18, 2026

(54) WIDEBAND CLASS-E AMPLIFIER

(71) Applicant: Ampleon Netherlands B.V., Nijmegen (NL)

(72) Inventors: Xuan Anh Nghiem, Nijmegen (NL); Radjindrepersad Gajadharsing, Nijmegen (NL)

(21) Appl. No.: 19/129,262

(22) PCT Filed: Nov. 13, 2023
(86) PCT No.: PCT/NL2023/050599

§ 371 Date: May 12, 2025

(30) Foreign Application Priority Data
Nov. 11, 2022 (NL) 2033512

(51) Int. Cl. H03F 3/24

(52) U.S. Cl. CPC H03F 3/245; H03F 2200/171; H03F 2200/451

(57) ABSTRACT

Example embodiments relate to wideband class-E amplifiers. One example embodiment includes a class-E radiofrequency, RF, amplifier. The class-E RF amplifier includes a power transistor configured to receive an input signal having a predetermined duty cycle. The power transistor includes an output and an output capacitance Cₒᵤₜ. The class-E RF amplifier also includes a class-E network connected to the output of the power transistor. The class-E network is configured to present a frequency-dependent impedance over a given operational frequency band at the output of the power transistor, wherein (i) the combination of the impedance of the class-E network seen at the output of the power transistor and the output capacitance Cₒᵤₜ matches, over the operational frequency band, (ii) an impedance profile that has been constructed using a model for a generalized class-E amplifier. The model includes a switching element and a generalized class-E network including a shunt capacitive network connected to an output of the switching element.

The present invention relates to a wideband class-E amplifier. More in particular, the present invention relates to a class-E radiofrequency, RF, amplifier based on Gallium Nitride high-power field-effect transistors operating in a frequency range between 1 MHz and 50 GHz and outputting power in a range between 0.1 and 1000 W.

Class-E amplifiers are known in the art, for example from “A Generalized High-Efficiency Broadband Class-E/F3 Power Amplifier Based on Design Space Expanding of Load Network” by Z. Yang et al, “Design of a Broadband High-Efficiency Hybrid Class-EFJ Power Amplifier” by Z. Zhang et al, and “High Efficiency and Wide Bandwidth Quasi-Load Insensitive Class-E Operation Utilizing Package Integration” by A. R. Qureshi et al.

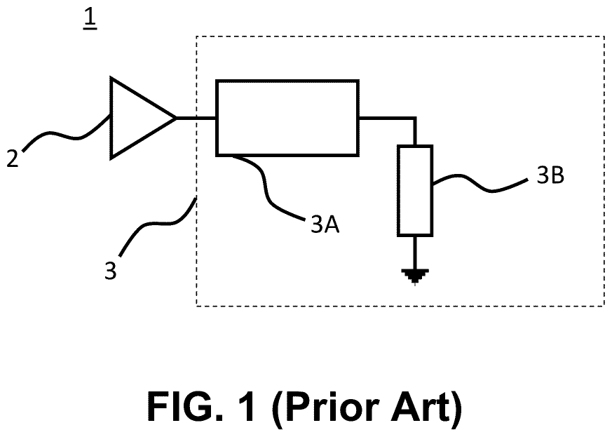

A schematic example of a generic class-E amplifier 1 is shown in FIG. 1. Class-E amplifier 1 is effectively a switching amplifier using a power transistor as a switching element 2 and having a tuned reactive network 3 coupled to an output of switching element 2. Tuned reactive network 3 comprises a mostly reactive part 3A and a resistive part 3B that comprises a load to which the amplified signal should be provided. Hereinafter, tuned reactive network 3 will be referred to as class-E network.

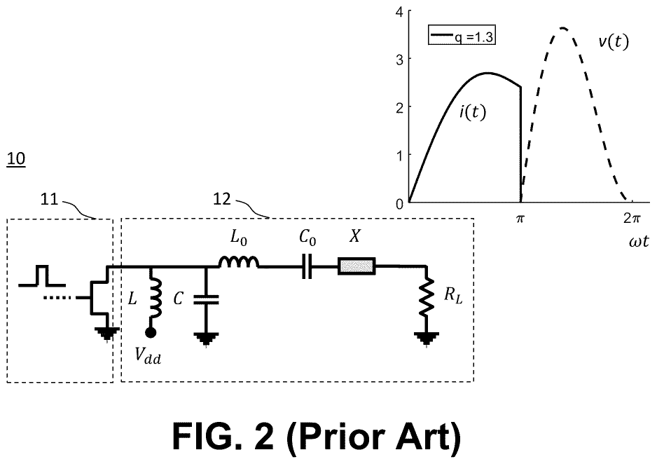

A more detailed example of a class-E amplifier 10 is provided in FIG. 2. Here, amplifier 10 is driven by a pulse signal having a predetermined duty cycle, which is typically 50%.

Class-E network 12 comprises a shunt inductor L that is typically used for biasing switching element 11. It further comprises a shunt capacitor C and a series resonance network consisting of an inductor L0 and a capacitor C0. The series resonance network is tuned to a target operational frequency, which typically corresponds to a center frequency of the operational frequency band the amplifier is designed to work in. Class-E network 12 further optionally comprises a reactive element X arranged in series with the series resonance network and a load R_{L}.

In ideal class-E operation of the class-E amplifier, the current waveforms i(t) and voltage waveforms v(t) are non-overlapping as shown in FIG. 2. In this manner, there is little to no power that is dissipated in the switching element. However, this behavior requires a particular combination of values of the various components of class-E network 12.

Analytical expressions for ensuring ideal class-E operation have been developed in “Analytical Design Equations for Class-E Power Amplifiers”, IEEE Transactions on Circuits and Systems”, by M. Acar et al, IEEE Transactions on Circuits and Systems I: Regular Papers, vol. 54, no. 12, pp. 2706-2717 December 2007. These equations allow the component values for L, C, X, and R_{L} to be computed as a function of supply voltage V_{dd}, output power Pₒᵤₜ, operational frequency ω, duty cycle d, and a factor q. This later factor is defined by:

$$q = \frac{1}{ω \sqrt{LC}} \qquad Eq . 1$$

More in particular, given a value for d and q, a set of K-values can be computed, which set comprises a value for K_{P}, a value for K_{L}, a value for K_{C}, and a value for K_{X}. In the remainder of this application, it will be assumed that the duty factor is fixed to a value of 50%. However, the skilled person will understand that the principles described in this application can easily be extended to other values for the duty cycle.

The K-values allow the component values of class-E network 12 to be computed according to:

$${R}_{L} = \frac{{K}_{P} ( q ) {V}_{dd , eff}^{2}}{{P}_{out}} \qquad Eq . 2$$

$$L = \frac{{K}_{L} ( q ) {K}_{P} ( q ) {V}_{dd , eff}^{2}}{ω {P}_{out}} \qquad Eq . 3$$

$$C = \frac{{K}_{C} ( q ) {P}_{out}}{ω {K}_{P} ( q ) {V}_{dd , eff}^{2}} \qquad Eq . 4$$

$$X = \frac{{K}_{X} ( q ) {K}_{P} ( q ) {V}_{dd , eff}^{2}}{{P}_{out}} \qquad Eq . 5$$

wherein V_{dd,eff}=V_{dd}−Vₖ with Vₖ being the knee voltage of the switching element. For an ideal switching element 11, Vₖ=0. With the components of the class-E network having the values determined in the manner described above, the abovementioned class-E operation is achieved with little to no overlap between the current and voltage waveforms. It is further noted that the class-E operation is less sensitive to the exact values of L0 and C0 provided that the resonance of the series resonance network occurs at the operational frequency ω. It is further noted that K_{P}(q), K_{L} (q), K_{C}(q), and K_{X}(q) are known functions of the q factor, which are typically given as an n^{th}-order polynomial function that is valid within a specific range of the q factor. Furthermore, for some values of the q factor, K_{X}(q) may be zero.

Depending on the value for q, different class-E modes can be distinguished. For example, a conventional class-E mode can be identified in cases for which shunt inductor L is very large, i.e. q<<0.5. A sub-harmonic class-E mode can be identified when q=0.5 and an even-harmonic class-E mode when q=2n, with n an integer larger than 0. A parallel-circuit class-E mode applies for q=1.412. This list is far from exhaustive and many more class-E networks and class-E modes are possible.

A problem with class-E networks in general is that the computed values only guarantee the desired class-E operation when the circuit is operated using the particular set of input parameters. This set includes a target operational frequency ω₀. However, amplifiers should typically be capable of operating over a given operational frequency band and for a certain range of loads. This means that the amplifier performs sub-optimally at frequencies ω that deviate from ω₀ and loads that deviate from calculated load R_{L}. In addition, the power transistors in class-E amplifiers that are used as switching elements comprise an output capacitance that may deteriorate performance if not properly accounted for.

An object of the present invention is to provide a class-E RF amplifier of the type described above that is less sensitive to changes in frequency and/or load impedance.

According to a first aspect, this object is achieved using the class-E RF amplifier as defined in claim 1, which is characterized in that the combination of the impedance of the class-E network seen at the output of the power transistor and the output capacitance of the power transistor matches over the operational frequency band to an impedance profile that has been constructed using a model for a generalized class-E amplifier. This model comprises a switching element, such as an ideal lossless switch, and a generalized class-E network, wherein a set of component values for the generalized class-E network for realizing class-E operation of the generalized class-E amplifier with non-overlapping current and voltage waveforms is uniquely defined given an operational frequency ω in the operational frequency band and a q factor.

The generalized class-E amplifier utilizes, at a target operational frequency ω₀ within the operational frequency band, a predefined q factor in a range between 1.2 and 1.4, more preferably between 1.25 and 1.35, even more preferably a predefined q factor equal to 1.3. Furthermore, at this frequency, a shunt capacitive network of the generalized class-E network connected to an output of the switching element has a capacitance C that equals a target capacitance C_{1,3}. At frequencies ω in the operational frequency band other than the target operational frequency ω₀, a different q factor is used such that the resulting capacitance C of the shunt capacitive network at those frequencies equals the target capacitance. The shunt capacitive network preferably comprises a capacitor of which a capacitance equals the output capacitance Cₒᵤₜ arranged in parallel to an inductor.

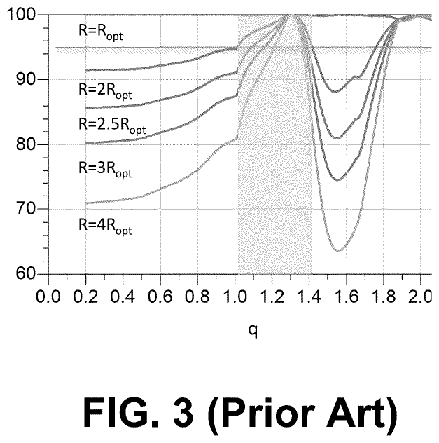

In known class-E RF amplifiers, the class-E network is determined at the target operational frequency ω₀. Furthermore, the q factor that is typically used for these RF amplifiers equals 1.3 as this value has proven to provide relative insensitivity to variations in the load impedance. This can be observed from FIG. 3, which illustrates the efficiency of a generalized class-E amplifier as a function of the q factor for various values of the load impedance. The Applicant has however found that this design methodology is inadequate for providing wideband performance.

According to the present invention, a generalized class-E amplifier is used to determine a desired impedance profile that represents the impedance that should be provided at the output of the power transistor, as much as possible, by the actual class-E network. The generalized class-E amplifier represents an idealized theoretical model of a physical class-E amplifier. Contrary to the actual physical class-E network used in the actual class-E RF amplifier, the component values of the generalized class-E amplifier are not fixed over frequency, with the exception of the capacitance C of the shunt capacitive network. This latter is kept fixed at the value it has when the operational frequency equals the target operational frequency ω₀ and when the q factor equals the predefined value. At other frequencies, the component values of the generalized class-E network are determined such that a) the calculated capacitance C of the shunt capacitive network equals the target capacitance C_{1,3}, and b) the values for the other components are such that ideal class-E operation can be obtained. The latter is only possible by allowing the q factor to vary over frequency. In fact, by imposing the abovementioned two requirements, a direct relation between the q factor and the operational frequency ω can be established.

Preferably, the capacitance C of the shunt capacitive network can be kept constant over frequency by appropriately changing the inductance of the inductor of the shunt capacitive network while keeping the capacitance of the capacitor of this network constant and equal to the output capacitance of the power transistor.

In modern day electronic design, computer-aided design, CAD, tools are used to determine the optimal values for component values of electric circuits. To this end, the CAD tools comprise one or more optimization algorithms. Typically, an optimization algorithm tries variations around an initial setting to determine an optimal condition. The outcome of such optimization generally depends strongly on the initial conditions and the design goals that are set. Optimizing the class-E network by comparing with an impedance profile that has been constructed using a model of a generalized class-E amplifier provides markedly different solutions than by solely focusing on the performance at the target operational frequency.

In accordance with the present invention, the impedance should be matched over the operational frequency band to the determined impedance profile. A suitable metric to determine whether a combination of component values of the class-E network is a suitable combination may comprise the error at a given frequency between the impedance of the impedance profile and the corresponding impedance of the combination of the class-E network and the output capacitance. This error can also be computed in a relative manner by dividing the abovementioned difference by the impedance of the combination of the class-E network and the output capacitance, or by the impedance of the impedance profile. Furthermore, the absolute value of this error or relative error can be taken. Furthermore, the error can be evaluated at the fundamental and/or harmonic frequencies. A combined error can be computed by summing the abovementioned errors or relative errors for a plurality of operational frequencies in the operational frequency band. Other metrics to determine the suitability of a class-E network are not excluded.

The Applicant has found that designing class-E networks such that the class-E network, in combination with the output capacitance, matches the abovementioned impedance profile provides a more broadband solution than a class-E network that is designed solely with the goal to provide optimal performance at the target operational frequency ω₀.

The generalized class-E network may further comprise a feed inductor L connected in between a power supply V_{dd} and the output of the switching element, a load Rz, a series resonance network tuned at an operational frequency ω and arranged in between the output of the switching element and the load R_{L}, and optionally, a reactive series component X arranged in series with the series resonance network. Furthermore, the q factor can be defined by Eq. 1, where it is noted that capacitance C in that equation corresponds to the capacitance of the shunt capacitive network at the corresponding operational frequency ω.

The impedance profile may comprise, for each of a plurality of operational frequencies within the operational frequency band, a first impedance seen at the output of the switching element at a fundamental frequency, hereinafter referred to as the fundamental, and a second impedance seen at the output of the switching element at a second harmonic frequency, hereinafter referred to as the second harmonic. By matching the impedance of the class-E network to these impedances, i.e. by matching the impedance of the combination of the class E-network and the output capacitance at the fundamental corresponding to a particular operational frequency to the first impedance of the impedance profile at that frequency, and by matching the impedance of the combination of the class E-network and the output capacitance at the second harmonic corresponding to that particular operational frequency to the second impedance of the impedance profile at that frequency, an improved matching can be obtained.

The set of component values for the generalized class-E network can be uniquely defined using a set of K values K_{P}(q), K_{L} (q), K_{C}(q), and K_{X}(q), that depend solely on the q factor and from which R_{L}, L, C, and X can be computed according to Eq. 2-Eq. 5. As stated above, the impact of a non-zero knee voltage can be taken into account. For example, a value for the knee voltage to be used in these equations may correspond to the knee voltage of the actual power transistor that is used for realizing the class-E RF amplifier.

The q factor at said other operational frequencies ω, i.e. different from the target operational frequency ω₀, may relate to those frequencies according to:

$$ω ( q ) = \frac{{K}_{C} ( q )}{{K}_{P} ( q )} \cdot \frac{{P}_{out}}{{C}_{1 , 3} {V}_{dd , eff}^{2}} \qquad Eq . 6$$

which equation can be derived from Eq. 4 by setting C to C_{1,3}.

Generally, the output capacitance Cₒᵤₜ of the power transistor is greater than C_{1,3}. In this case, the class-E network may comprise a shunt network connected to the output of the power transistor of which the effective inductance L_{R} at a frequency nω₀ equals:

$${L}_{R} = \frac{1}{{n}^{2} {ω}_{0}^{2} ( {C}_{out} - {C}_{1 , 3} )} \qquad Eq . 7$$

wherein n is an integer equal to or greater than 1, and preferably equal to 1 or 2. In this manner, the excess capacitance Cₒᵤₜ−C_{1,3} can be tuned out either at the fundamental or at the second harmonic.

The class-E network may further comprise a filter being a low-pass filter, a high-pass filter, or a band-pas filter, and being connected in between the output of the power transistor and an intermediate node. A phase delay element can be arranged in between an output of the class-E RF amplifier and the filter. The class-E network may additionally comprise a biasing network arranged in between the output of the class-E RF amplifier and a power supply. The biasing network is configured to provide, at an operational frequency within the operational frequency band, an RF open seen looking into the biasing network from the output of the class-E RF amplifier at the fundamental, and an RF short at the second harmonic.

The filter can be a low-pass filter comprising a series inductor connected in between the output of the power transistor and the intermediate node, and a shunt capacitor connected to the intermediate node. In case the filter is a band-pas filter, the filter may comprise a parallel connection of an inductor and a capacitor that is tuned to the target operational frequency.

According to a second aspect, the present invention provides a class-E radiofrequency, RF, amplifier that comprises a power transistor and a class-E network connected to an output of the power transistor, wherein the power transistor comprises an output and an output capacitance Cₒᵤₜ and is configured to receive an input signal having a predetermined duty cycle.

The power transistor is configured to output power at a given level Pₒᵤₜ, and at a target operational frequency ω₀ within a operational frequency band. Furthermore, the class-E network comprises a series inductor arranged in between the output of the power transistor and an intermediate node, a shunt capacitor connected to the intermediate node, a phase delay connected in between the intermediate node and an output of the class-E RF amplifier, and a biasing network connected in between a power supply and the output of the class-E RF amplifier of which an impedance seen from the output of the class-E RF amplifier at an operational frequency within the operational frequency band corresponds to an RF open at the fundamental and an RF short at the second harmonic. The class-E network further comprises a shunt network that is connected to the output of the power transistor.

An effective inductance L_{R} of the shunt network at a frequency nω₀ may equal:

$${L}_{R} = \frac{1}{{n}^{2} {ω}_{0}^{2} ( {C}_{out} - {C}_{1 , 3} )} \qquad Eq . 9$$

wherein n is an integer equal to or greater than 1, and preferably equal to 1 or 2; and wherein C_{1,3} is a target capacitance a capacitance C of a shunt capacitive network of a generalized class-E network of a generalized class-E amplifier would be equal to at the target operational frequency ω₀ with a q factor lying in a range between 1.25 and 1.35.

The generalized class-E amplifier may comprise a switching element of which an output is connected to the generalized class-E network. The shunt capacitive network can be connected to an output of the switching element.

The generalized class-E network may further comprise the following components a) a feed inductor connected in between a power supply V_{dd} and the output of the switching element, b) a load R_{L}, c) a series resonance network tuned at a target operational frequency ω₀ and arranged in between the output of the switching element and the load R_{L}, and d) an optional reactive series component X arranged in series with the series resonance network.

A set of component values for the generalized class-E network for realizing class-E operation of the generalized class-E amplifier with non-overlapping current and voltage waveforms can be uniquely defined given an operational frequency ω in the operational frequency band and the q factor, wherein the q factor is defined by:

$$q = \frac{1}{ω \sqrt{LC}} \qquad Eq . 10$$

The topology described above allows the combined impedance of the class-E network and the output capacitance of the power transistor to be matched to the impedance of the generalized class-E network over the operational frequency band. For the generalized class-E network, the capacitance of the shunt capacitive network may equal the target capacitance and the q factor varies over frequency to allow class-E operation with non-overlapping current and voltage waveforms at each frequency in the operational frequency band. In this manner, a wide band solution can be obtained in which class-E operation can be ensured.

A set of component values for the generalized class-E network can be uniquely defined using a set of K values K_{P}(q), K_{L} (q), K_{C}(q), and K_{X}(q), that depend solely on the q factor and from which R_{L}, L, C, and X can be computed according to:

$${R}_{L} = \frac{{K}_{P} ( q ) {V}_{dd , eff}^{′2}}{{P}_{out}} \qquad Eq . 11$$

$$L = \frac{{K}_{L} ( q ) {K}_{P} ( q ) {V}_{dd , eff}^{2}}{ω {P}_{out}} \qquad Eq . 12$$

$$C = \frac{{K}_{C} ( q ) {P}_{out}}{ω {K}_{P} ( q ) {V}_{dd , eff}^{2}} \qquad Eq . 13$$

$$X = \frac{{K}_{X} ( q ) {K}_{P} ( q ) {V}_{dd , eff}^{2}}{{P}_{out}} \qquad Eq . 14$$

The shunt capacitor of the class-E network can be connected to ground through a further inductor for allowing a better match between the impedance seen at the output of the power transistor and the impedance provided by the generalized class-E network.

The shunt network of the class-E network may comprise a shunt inductor L_{R1} that is connected with a first terminal thereof to the output of the power transistor and with a second terminal thereof to ground via a first DC blocking capacitor C₂, and to ground through a further inductor L_{R2} in series with a second DC blocking capacitor C₃.

A resonance frequency associated with a series resonance of the further inductor L_{R2} and the second DC blocking capacitor C₃ equals a first resonance frequency ω₁, and a resonance frequency associated with the parallel resonance of the further inductor L_{R2} and the first DC blocking capacitor C₂ equals a second resonance frequency ω₂, wherein ω₁<ω₂. The resonance frequency associated with the series resonance between the parallel connection of the first DC blocking capacitor C₂ and the further inductor L_{R2} and the shunt inductor L_{R1} equals ω₃, wherein ω₂<ω₃.

Preferably, ω₁ deviates from the target operational frequency by a value in the range between 0.1 and 10 percent of the target operational frequency ω₀, ω₂ preferably deviates from the target operational frequency by a value in the range between 5 and 20 percent of the target operational frequency ω₀, and ω₃ preferably deviates from the target operational frequency by a value in the range between 10 and 30 percent of the target operational frequency ω₀. Optionally, a resistor or other resistive element is arranged in series with the further inductor L_{R2} and the second DC blocking capacitor C₂ for damping any impedance peaks that may occur in or near the video band.

The abovementioned network including the further inductor allows proper definition of the impedance seen at the output of the power amplifier in the video band of the class-E RF amplifier.

The biasing network may comprise a quarter wavelength transmission line or equivalent thereof of which one end is connected to the output of the RF class-E amplifier and an other end to the power supply and to a grounded DC decoupling capacitor. The DC decoupling capacitor ensures an RF ground at the fundamental and harmonics. This RF ground is transformed by the quarter wavelength transmission line into an RF open, whereas an RF ground is created at even harmonics. The transmission line in between the filter and output of the class-E RF amplifier allows further optimization of the harmonic impedances to be presented at the output of the power transistor.

The power transistor can be a Gallium Nitride-based field-effect transistor or a laterally diffused metal-oxide-semiconductor transistor. Furthermore, the load may comprise a resistive load and an impedance matching network arranged in between the output of the class-E RF amplifier and the resistive load, wherein the impedance matching network comprises a quarter wavelength transmission line or equivalent thereof. In some cases, the optimal load impedance for ensuring class-E operation does not correspond to the actual load to which power should be delivered. In those cases, an impedance matching network can be used to bridge the difference between these impedances.

The operational frequency band may correspond to a frequency band in between 10 and 30 percent of the target operational frequency and relative to the target operational frequency, preferably in between 10 and 20, and wherein the target operational frequency lies within the range between 1 MHz and 50 GHz, more preferably between 1 and 20 GHz. Furthermore, the maximum power outputted by the RF class-E amplifier may lie in a range between 0.1 and 1000 W, preferably between 5 and 500 W.

Next, the present invention will be described in more detail referring to the appended drawings, wherein similar or identical components will be referred to using the same reference signs, and wherein:

FIG. 1 illustrates a generic class-E amplifier;

FIG. 2 illustrates a generalized class-E amplifier having a known topology and its corresponding I-V behavior;

FIG. 3 illustrates the efficiency of the class-E amplifier of FIG. 2 as a function of q factor for different loads;

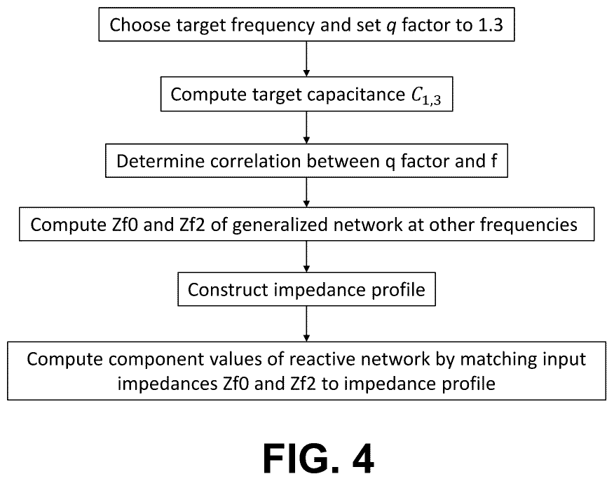

FIG. 4 illustrates a method for designing a class-E amplifier in accordance with the present invention;

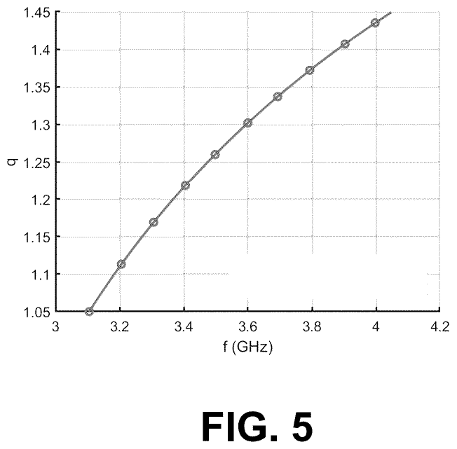

FIG. 5 illustrates the q factor as a function of frequency in accordance with the present invention;

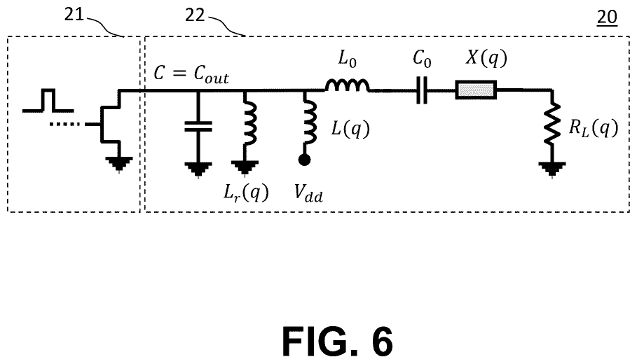

FIG. 6 illustrates the generalized class-E amplifier used for construction the impedance profile in accordance with the present invention;

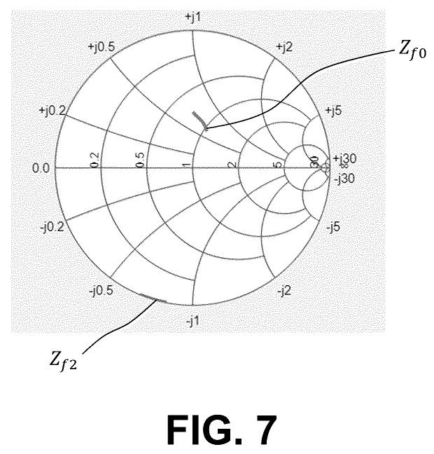

FIG. 7 illustrates an impedance profile constructed using the generalized class-E amplifier;

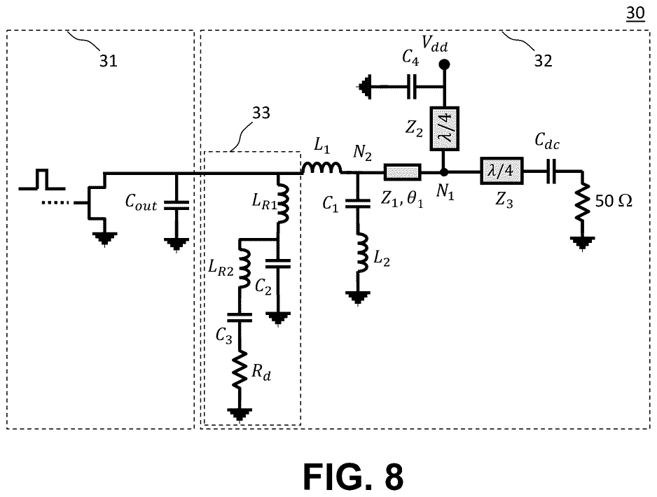

FIG. 8 illustrates an embodiment of a class-E RF amplifier in accordance with the present invention; and

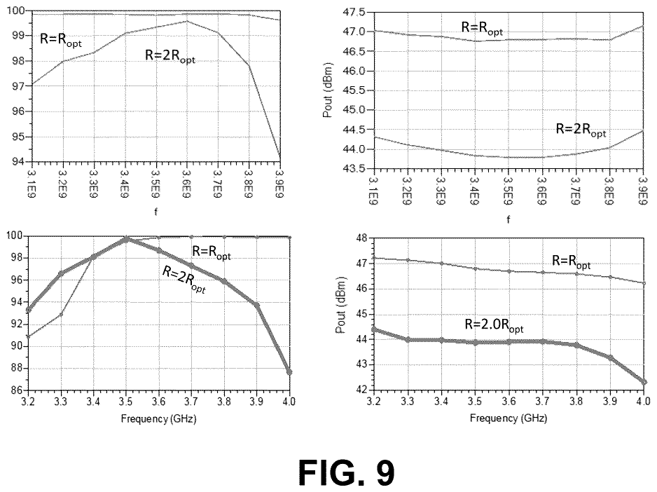

FIG. 9 illustrates efficiency and output power for different loads over frequency for the class-E amplifier in accordance with the present invention.

FIG. 4 illustrates a method for designing a class-E amplifier in accordance with the present invention. It is assumed that this amplifier is configured for outputting a certain power Pₒᵤₜ within a given operational frequency band with a certain duty cycle using a given supply voltage V_{dd}.

As a first step, a target operational frequency ω₀ is chosen, which typically corresponds to a center frequency within the operational frequency band. As a next step, the generalized class-E amplifier depicted in FIG. 2 is used for calculating the impedance profile. This calculation starts with computing the capacitance of shunt capacitor C. For this calculation it is assumed that the q factor equals 1.3. As Pₒᵤₜ, V_{dd}, ω₀, the duty factor, Vₖ, and the q factor are known, a set of K values K_{P}(q), K_{L}(q), K_{C}(q), and K_{X}(q) can be calculated using the following polynomial equations that have been obtained by curve fitting the corresponding analytical equations disclosed in “Analytical Design Equations for Class-E Power Amplifiers”, IEEE Transactions on Circuits and Systems”, by M. Acar et al, IEEE Transactions on Circuits and Systems I: Regular Papers, vol. 54, no. 12, pp. 2706-2717 December 2007:

$${K}_{L} ( q ) = 8.0 \; 203 {q}^{2} - 24.3 \; 591 q + 19 \text{.1203} \qquad Eq . 15$$

$${K}_{P} ( q ) = - 11.8 \; 45 {q}^{3} + 42.5 \; 273 {q}^{2} - 49.3 \; 462 q + 19.5 \; 852 \qquad Eq . 16$$

$${K}_{C} ( q ) = - 6.9 \; 733 {q}^{3} + 25.9 \; 35 {q}^{2} - 31.0 \; 796 q + 12.4 \; 889 \qquad Eq . 17$$

$${K}_{X} ( q ) = - 2.9 \; 446 {q}^{3} + 8.9 \; 872 {q}^{2} - 10.4 \; 421 q + 5.1172 \qquad Eq . 18$$

Here, it is noted that Vₖ corresponds to the knee voltage of the power transistor in the actual class-E RF amplifier. Having determined the K values, shunt capacitance C can be calculated using Eq. 4. This capacitance value is referred to as the target capacitance C_{1,3}. As a next step, a correlation between the q factor and operational frequency ω is determined using Eq. 6. A result of this correlation is shown in FIG. 5. It is noted that the q factor for a given operational frequency is that q factor which would result in ideal class-E operation of generalized class-RF amplifier 10 with the boundary condition that C=C_{1,3}. The generalized class-E RF amplifier can then be represented as generalized class-E RF amplifier 20 shown in FIG. 6.

In the generalized class-E RF amplifier 20, the shunt capacitor C has been replaced by a parallel connection of an inductor and a capacitor having a capacitance that is equal to the output capacitance of the power transistor that is to be used in amplifier 20. This parallel connection is jointly referred to as shunt capacitive network. The inductance of the inductor in this network can be calculated by imposing that at a given operational frequency ω, the resulting capacitance of the shunt capacitive network equals C_{1,3}.

In generalized class-E network 22, all component values except for the capacitance of the shunt capacitive network are dependent on the q factor. Component values for inductor L₀ and capacitor C₀ should be chosen such that the corresponding resonant frequency equals the operational frequency ω of the signal that is applied to switching element 21.

As a next step, generalized class-E RF amplifier 20 is used for calculating an impedance profile. This impedance profile is constructed using a small-signal analysis at a plurality of operational frequencies. More in particular, the impedance at the output of switching element 21 seen looking towards generalized class-E network 22 is determined both at the fundamental and at the second harmonic for a plurality of operational frequencies. The impedance determined at the fundamental is referred to as the first impedance Z_{f0} and the impedance determined at the second harmonic is referred to as the second impedance Z_{f2}. An example of such impedances is shown in FIG. 7.

According to the present invention, impedances Z_{f0} and Z_{f2} are used as the impedances that the power transistor of the actual class-E amplifier should see at its intrinsic output within the operational frequency band. This power transistor can be a Gallium Nitride field-effect transistor or a Silicon based laterally diffused metal-oxide-semiconductor transistor.

According to the present invention, impedances Z_{f0} and Z_{f2} are used as design goals when determining the values of the various components of the class-E network that is to be connected to the power transistor.

A particularly advantageous network topology for matching the determined impedance profile is shown in FIG. 8. In this amplifier, the power transistor that forms switching element 31 has an output capacitance Cₒᵤₜ. This capacitance generally deviates from target capacitance C_{1,3}. As a result, the power transistor sees at its intrinsic output a combination of the input impedance of class-E network 32 and output capacitance Cₒᵤₜ. According to the present invention, the difference between Cₒᵤₜ and C_{1,3} can be mitigated by connecting a shunt network 33 connected to the output of the power transistor. Preferably at the fundamental, shunt network 33 behaves as a shunt inductance of which the inductance value is given by Eq. 9 with n=1. It should be noted that shunt network 33 has similar functionality as the inductor of the shunt capacitive network of the generalized class-E network 20 in FIG. 6.

In FIG. 8, shunt network 33 comprises a first shunt inductor L_{R1} that is connected to ground via a first DC blocking capacitor C₂ and via a series connection of second shunt inductor L_{R2} and a second DC blocking capacitor C₃. To dampen resonances at video-band frequencies, a resistance Ra is arranged in series with L_{R2}. It is noted that C₃>>C₂.

Shunt network 33 displays various resonances. For example, a first resonance is the series resonance between L_{R2} and C₃. This resonance is described using first resonance frequency ω₁. A second resonance is the resonance between L_{R2} and C₂. This resonance is described using second resonance frequency ω₂. A third resonance is the resonance between L_{R1} and the parallel connection of L_{R2} and C₂. This resonance is described using third resonance frequency ω₃.

To improve the video bandwidth behavior of the amplifier, it is preferred to prevent high impedances in that bandwidth. This can be best achieved when the following conditions are met ω₁<<ω₂, ω₂<ω₃, and ω₃<<ω₀.

Typically, resonance frequency ω₁ lies in the frequency range between 0.1 and 10 percent of ω₀, resonance frequency ω₂ in the frequency range between 5 and 20 percent of ω₀, and resonance frequency ω₃ in the frequency range between 10 and 30 percent of ω₀.

Class-E network 32 further comprises a low-pass filter, which in FIG. 8 is embodied as a series inductor L₁ and shunt capacitor C₁. This filter is arranged in between the output of the power transistor and an intermediate node N₂. Compared to a band-pas filter using a series combination of an inductor and a capacitor, the low-pass filter is a more compact solution. It should however be noted that the present invention does not exclude other types of filters to be used instead of the low-pass filter shown in FIG. 8.

Class-E network 32 also comprises a transmission line having a characteristic impedance Z₁ and electrical length θ₁. This transmission line is arranged in between intermediate node N₂ and output of class-E amplifier 30, here referred to as node N₁.

Output N₁ is connected to a power supply V_{dd} via a quarter wavelength transmission line Z₂. At one end of transmission line Z₂, a DC decoupling capacitor C₄ is used to ensure that this end is RF grounded. Consequently, output N₁ sees an RF open looking towards power supply V_{dd} at the fundamental and at odd harmonic frequencies. At the second harmonic or even harmonics in general, an RF short is seen. Using transmission line Z₁, the impedance at the fundamental and second harmonic can be transformed such that, in combination with the low-pass filter and shunt network 33, impedances are presented at the intrinsic output of the power transistor that match Z_{f0} and Z_{f2} as best as possible.

Typically, the load required for class-E operation is different from the actual load that is to be connected to the amplifier. To address this issue, one or more impedance matching networks can be arranged in between output N₁ and the load. FIG. 8 presents an example in which a quarter wavelength transmission line Z₃ is used for achieving such impedance matching.

To determine the various components of class-E amplifier 30, the following approach can be followed. Using CAD software, the impedances seen at the output of the power transistor can be compared with the impedance profile. The outcome of this comparison can be used as an error function when optimizing the various components of amplifier 30. During the optimization, the value of the load, 50 Ohm in FIG. 8, and output capacitance Cₒᵤₜ are fixed.

FIG. 9 illustrates the behavior of class-E amplifier 20 as a function of frequency for two different loads for the case Cₒᵤₜ=C_{1,3} (figures on the top) and that of the class-E amplifier 30 after optimization (figure on the bottom). A first load, referred to as Rₒₚₜ, represents the load that was used during optimization, whereas 2Rₒₚₜ represents a load twice that value corresponding to back-off load-state of a load modulation amplifier, such as a Doherty amplifier. As can be seen from the figures, both efficiency (figures on the left) and output power (figures on the right) remain relatively constant over 20% fractional bandwidth.

It is noted that the abovementioned methodology can be used for various types of class-E networks provided that these networks provide a suitable match to the impedance profile. In that respect, the class-E network shown in FIG. 8 is an advantageous example.

To qualify as a suitable match, the following error metric could be used:

$$error = α \frac{1}{N} {\sum }_{n = 1}^{n = N} \frac{\vert {Z}_{f 0 , n} - {Z}_{f 0 , n}^{*} \vert}{\vert {Z}_{f 0 , n} \vert} + β \frac{1}{N} {\sum }_{n = 1}^{n = N} \frac{\vert {Z}_{f 2 , n} - {Z}_{f 2 , n}^{*} \vert}{\vert {Z}_{f 2 , n} \vert} \qquad Eq . 19$$

wherein a and B are weighing factors, which can be set to one, Z_{f0,n} and Z_{f2,n} impedances of the impedance profile at the fundamental and second harmonic, respectively, for a given operational frequency ωn,

$${Z}_{f 0 , n}^{*} and {Z}_{f 2 , n}^{*}$$

impedances seen at the output of the power transistor of class-E amplifier 30 at that fundamental and second harmonic, respectively, that correspond to the combination of Cₒᵤₜ and the input impedance of class-E network 32, and N the total number of operational frequencies for which the comparison is made.

The abovementioned metric represents the sum of the average relative error in the impedance at the fundamental and second harmonic. Exemplary values for this metric are:

$$\frac{1}{N} {\sum }_{n = 1}^{n = N} \frac{\vert {Z}_{f 0 , n} - {Z}_{f 0 , n}^{*} \vert}{\vert {Z}_{f 0 , n} \vert} << {E}_{1} \qquad Eq . 20$$

$$\frac{1}{N} {\sum }_{n = 1}^{n = N} \frac{\vert {Z}_{f 2 , n} - {Z}_{f 2 , n}^{*} \vert}{\vert {Z}_{f 2 , n} \vert} << {E}_{2} \qquad Eq . 21$$

wherein E₁ is 1e-2, preferably 1e-3, and more preferably 1e-6, and wherein E₂ is 0.1, preferably 1e-2, and more preferably 1e-4.

In the above, the present invention was described using detailed embodiments thereof. However, the present invention is not limited to these embodiments and various modifications are possible without deviating from the scope of the present invention which is defined by the appended claims and their equivalents. For example, in embodiments wherein C_{1,3}>Cₒᵤₜ, the shunt capacitive network of the generalized class-E network will only comprise a capacitor with a capacitance equal to C_{1,3}, and the shunt network of the actual class-E network will behave capacitively to compensate for Cₒᵤₜ being smaller than C_{1,3}.

1. A class-E radiofrequency, RF, amplifier, comprising:
a power transistor configured to receive an input signal having a predetermined duty cycle, the power transistor comprising an output and an output capacitance Cₒᵤₜ; and
a class-E network connected to the output of the power transistor, wherein the class-E network is configured to present a frequency-dependent impedance over a given operational frequency band at the output of the power transistor,
wherein (i) the combination of the impedance of the class-E network seen at the output of the power transistor and the output capacitance Cₒᵤₜ matches, over the operational frequency band, (ii) an impedance profile that has been constructed using a model for a generalized class-E amplifier, wherein the model comprises a switching element and a generalized class-E network including a shunt capacitive network connected to an output of the switching element,
wherein, for each operational frequency ω within the operational frequency band and given a q factor of the generalized class-E network, a set of component values for the generalized class-E network for realizing class-E operation of the generalized class-E amplifier with non-overlapping current and voltage waveforms is uniquely defined,
wherein the generalized class-E amplifier utilizes:
at a target operational frequency ω₀ within the operational frequency band, a predefined q factor in a range between 1.2 and 1.4 and the shunt capacitive network of the generalized class-E network having a capacitance C that equals a target capacitance C_{1,3}, and
at other frequencies ω in the operational frequency band, using corresponding sets of component values, a different q factor such that the resulting capacitance C of the shunt capacitive network at those frequencies equals the target capacitance C_{1,3}, and
wherein the predefined q factor lies in a range between 1.25 and 1.35.

2. The class-E RF amplifier according to claim 1, wherein the shunt capacitive network comprises a capacitor arranged in parallel to an inductor, and wherein the capacitor has a capacitance equal to the output capacitance Cₒᵤₜ.

3. The class-E RF amplifier according to claim 1, wherein the generalized class-E network further comprises:
a feed inductor L connected in between a power supply V_{dd} and the output of the switching element;
a load R_{L};
a series resonance network tuned at an operational frequency ω and arranged in between the output of the switching element and the load R_{L}; and
an optional reactive series component X arranged in series with the series resonance network,
wherein the q factor is defined by:
$$q = \frac{1}{ω \sqrt{LC}}$$
wherein the impedance profile comprises, for each of a plurality of operational frequencies within the operational frequency band, a first impedance Z_{f0} seen at the output of the switching element at a fundamental frequency and a second impedance Z_{f2} seen at the output of the switching element at a second harmonic frequency.

4. The class-E RF amplifier according to claim 1, wherein the set of component values for the generalized class-E network is uniquely defined using a set of K values K_{P}(q), K_{Z}(q), K_{C}(q), and K_{X}(q), that depend solely on the q factor and from which R_{L}, L, C, and X can be computed according to:
$${R}_{L} = \frac{{K}_{P} ( q ) {V}_{dd , eff}^{2}}{{P}_{out}}$$
$$L = \frac{{K}_{L} ( q ) {K}_{P} ( q ) {V}_{dd , eff}^{2}}{ω {P}_{out}}$$
$$C = \frac{{K}_{C} ( q ) {P}_{out}}{ω {K}_{P} ( q ) {V}_{dd , eff}^{2}}$$
$$X = \frac{{K}_{X} ( q ) {K}_{P} ( q ) {V}_{dd , eff}^{2}}{{P}_{out}}$$
wherein Pₒᵤₜ is the power outputted by the generalized class-E RF amplifier, and V_{dd,eff}=V_{dd}−Vₖ, wherein V_{dd} is the supply voltage and Vₖ the knee voltage of the power transistor of the class-E RF amplifier, and
wherein the q factor at said other operational frequencies ω relates to those frequencies according to:
$$ω ( q ) = \frac{{K}_{C} ( q )}{{K}_{P} ( q )} \cdot \frac{{P}_{out}}{{C}_{1 , 3} {V}_{dd , eff}^{2}} \underline{.}$$

5. The class-E RF amplifier according to claim 1,
wherein the output capacitance Cₒᵤₜ is greater than C_{1,3}, and
wherein:
the class-E network comprises a shunt network connected to the output of the power transistor of which the effective inductance L_{R} at a frequency nω₀ equals:
$${L}_{R} = \frac{1}{{n}^{2} {ω}_{0}^{2} ( {C}_{out} - {C}_{1 , 3} )}$$
wherein n is an integer equal to or greater than 1.

6. A class-E radiofrequency, RF, amplifier, comprising:
a power transistor; and
a class-E network connected to an output of the power transistor, wherein the power transistor comprises an output and an output capacitance Cₒᵤₜ and is configured to receive an input signal having a predetermined duty cycle,
wherein the power transistor is configured to output power at a given level Pₒᵤₜ, and at a target operational frequency ω₀ within a operational frequency band,
wherein the class-E network comprises:
a series inductor (L1) arranged in between the output of the power transistor and an intermediate node (N₂);
a shunt capacitor (C1) connected to the intermediate node (N₂);
a phase delay connected in between the intermediate node (N₂) and an output (N₁) of the class-E RF amplifier;
a biasing network connected in between a power supply and the output (N₁) of the class-E RF amplifier, wherein an impedance of the biasing network seen from the output of the class-E RF amplifier at an operational frequency ω within the operational frequency band corresponds to an RF open at the fundamental frequency and an RF short at the second harmonic; and
a shunt network connected to the output of the power transistor.

7. The class-E RF amplifier according to claim 6, wherein an effective inductance L_{R} of the shunt network at a frequency nω₀ equals:
$${L}_{R} = \frac{1}{{n}^{2} {ω}_{0}^{2} ( {C}_{out} - {C}_{1 , 3} )}$$
wherein n is an integer equal to or greater than 1, and
wherein C_{1,3} is a target capacitance C of a shunt capacitive network of a generalized class-E network of a generalized class-E amplifier at the target operational frequency ω₀ with a q factor lying in a range between 1.25 and 1.35.

8. The class-E RF amplifier according to claim 7, wherein the generalized class-E amplifier comprises a switching element of which an output is connected to the generalized class-E network, and wherein the shunt capacitive network is connected to an output of the switching element,
wherein the generalized class-E network further comprises:
a feed inductor L connected in between a power supply V_{dd} and the output of the switching element;
a load R_{L};
a series resonance network tuned at a target operational frequency ω₀ and arranged in between the output of the switching element and the load Rz; and
an optional reactive series component X arranged in series with the series resonance network,
wherein a set of component values for the generalized class-E network used for class-E operation of the generalized class-E amplifier with non-overlapping current and voltage waveforms is uniquely defined for each operational frequency ω within the operational frequency band given the q factor, and
wherein the q factor is defined by:
$$q = \frac{1}{ω \sqrt{LC}}$$

9. The class-E RF amplifier according to claim 6, wherein the shunt capacitor (C₁) of the class-E network is connected to ground through a further inductor (L2).

10. The class-E RF amplifier according to claim 6, wherein the shunt network of the class-E network comprises:
a shunt inductor L_{R1} is connected:
with a first terminal thereof to the output of the power transistor;
with a second terminal thereof to ground via a first DC blocking capacitor C₂; and
to ground through a further inductor L_{R2} in series with a second DC blocking capacitor C₃, wherein:
wherein a resonance frequency associated with a series resonance of the further inductor L_{R2} and the second DC blocking capacitor C₃ equals a first resonance frequency ω₁,
wherein a resonance frequency associated with the parallel resonance of the further inductor L_{R2} and the first DC blocking capacitor C₂ equals a second resonance frequency ω₂,
wherein ω₁<ω₂, and
wherein a resonance frequency associated with the series resonance between the parallel connection of (i) the first DC blocking capacitor C₂ and the further inductor L_{R2} and (ii) the shunt inductor L_{R1} equals ω₃, wherein ω₂<ω₃.

11. The class-E RF amplifier according to claim 6, wherein the biasing network comprises a quarter wavelength transmission line (Z₂) or equivalent thereof of which one end is connected to the output (N₁) of the class-E RF amplifier and another end to the power supply and to a grounded DC decoupling capacitor C₄.

12. The class-E RF amplifier according to claim 6, wherein the power transistor is a Gallium Nitride-based field-effect transistor or a laterally diffused metal-oxide-semiconductor transistor.

13. The class-E RF amplifier according to claim 6, wherein the load comprises a resistive load and an impedance matching network arranged in between the output of the class-E RF amplifier and the resistive load, and wherein the impedance matching network comprises a quarter wavelength transmission line or equivalent thereof.

14. The class-E RF amplifier according to claim 6, wherein the operational frequency band corresponds to a frequency band in between 10 and 30 percent of the target operational frequency relative to the target operational frequency, and wherein the target operational frequency lies within the range between 1 MHz and 50 GHz.

15. The class-E RF amplifier according to claim 6, wherein the maximum power outputted by the RF class-E amplifier lies in a range between 0.1 and 1000 W.

16. The class-E RF amplifier according to claim 1, wherein the predefined q factor equals 1.3.

17. The class-E RF amplifier according to claim 5, wherein the class-E network further comprises:
a filter being a low-pass filter, a high-pass filter, or a band-pass filter, and being connected in between the output of the power transistor and an intermediate node (N₂), wherein the filter is a low-pass filter comprising a series inductor (L₁) connected in between the output of the power transistor and the intermediate node (N₂), and a shunt capacitor (C1) connected to the intermediate node (N₂);
a phase delay element arranged in between an output (N₁) of the class-E RF amplifier and the filter; and
a biasing network arranged in between the output (N₁) of the class-E RF amplifier and a power supply V_{dd},
wherein the biasing network is configured to provide, at an operational frequency within the operational frequency band, an RF open seen looking into the biasing network from the output (N₁) of the class-E RF amplifier at the fundamental, and an RF short at the second harmonic.

18. The class-E RF amplifier according to claim 8, wherein a set of component values for the generalized class-E network is uniquely defined using a set of K values K_{P}(q), K_{Z}(q), K_{C}(q), and K_{X}(q), that depend solely on the q factor and from which R_{L}, L, C, and X can be computed according to:
$${R}_{L} = \frac{{K}_{P} ( q ) {V}_{dd , eff}^{2}}{{P}_{out}}$$
$$L = \frac{{K}_{L} ( q ) {K}_{P} ( q ) {V}_{dd , eff}^{2}}{ω {P}_{out}}$$
$$C = \frac{{K}_{C} ( q ) {P}_{out}}{ω {K}_{P} ( q ) {V}_{dd , eff}^{2}}$$
$$X = \frac{{K}_{X} ( q ) {K}_{P} ( q ) {V}_{dd , eff}^{2}}{{P}_{out}}$$
wherein V_{dd,eff}=V_{dd}−Vₖ, wherein V_{dd} is the supply voltage and Vₖ the knee voltage of the power transistor of the class-E RF amplifier.

19. The class-E RF amplifier according to claim 10, wherein ω₁ deviates from the target operational frequency by a value between 0.1 and 10 percent of the target operational frequency ω₀, ω₂ deviates from the target operational frequency by a value between 5 and 20 percent of the target operational frequency ω₀, and ω₃ deviates from the target operational frequency by a value between 10 and 30 percent of the target operational frequency ω₀.
